(19) United States
(12) Patent Application Publication
(10) Pub. No.: US 2025/0277863 A1
(43) Pub. Date: Sep. 4, 2025

(54) BATTERY SOC EVALUATION METHOD, APPARATUS, DEVICE AND MEDIUM

(71) Applicant: Beijing HyperStrong Technology Co., Ltd., Beijing (CN)

(72) Inventors: Hao MA, Beijing (CN); Zhichao HE, Beijing (CN); Guang YANG, Beijing (CN)

(21) Appl. No.: 18/680,729

(22) Filed: May 31, 2024

(30) Foreign Application Priority Data
Mar. 4, 2024 (CN) 202410245133.9

(51) Int. Cl. G01R 31/388; G01R 31/367; G01R 31/374; G01R 31/396

(52) U.S. Cl. CPC G01R 31/388; G01R 31/367; G01R 31/374; G01R 31/396

(57) ABSTRACT

The present application provides a battery SOC evaluation method, an apparatus, a device and a medium. The method includes: acquiring charging-discharging data of a first battery cell pack at different first temperatures and different first rates, where the number of the first battery cell pack is at least one, and the first battery cell pack includes a first battery cell; acquiring first SOCs of the first battery cell pack according to the charging-discharging data, where the charging-discharging data includes first voltages of the first battery cell pack; establishing an association table of the first SOCs with the first temperatures, the first rates and the first voltages; acquiring a second temperature, a second rate and a second voltage of a battery pack, and acquiring a second SOC of each second battery cell in the battery pack by the association table, where the battery pack includes multiple second battery cells.

### CROSS-REFERENCE TO RELATED APPLICATION

This application claims priority to Chinese Patent Application No. 202410245133.9, filed on Mar. 4, 2024, which is hereby incorporated by reference in its entirety.

### TECHNICAL FIELD

The present application relates to the field of battery technology and, in particular, to a battery SOC evaluation method, an apparatus, a device and a medium.

### BACKGROUND

Battery state of charge (SOC), as a quantitative evaluation of a state of charge stored within a battery, is used to characterize the ability of an energy storage system to store/release remaining power, and to prevent over-charge and over-discharge of the battery and ensure the safety of the energy storage system. However, the battery SOC cannot be measured directly, but can only be obtained by external characteristic parameters such as a voltage of the battery.

Existing methods for battery SOC estimation incorporate many algorithms, including a data-driven method, a Kalman filtering method, etc. However, these algorithms are used to perform overall evaluation on a battery system, and do not evaluate each battery cell of the battery system, which leads to inaccurate evaluation results.

Therefore, the present application proposes an evaluation method that can improve the accuracy of SOC evaluation.

### SUMMARY

The present application provides a battery SOC evaluation method, an apparatus, a device and a medium, which are used for solving problems of lacking analysis on a battery cell of a battery system and a result of battery SOC evaluation being not accurate enough in the prior art.

In a first aspect, the present application provides a battery SOC evaluation method, including:
acquiring charging-discharging data of a first battery cell pack at different first temperatures and different first rates, where the number of the first battery cell pack is at least one, and the first battery cell pack includes a first battery cell;
acquiring first SOCs of the first battery cell pack according to the charging-discharging data, where the charging-discharging data includes first voltages of the first battery cell pack;
establishing an association table of the first SOCs with the first temperatures, the first rates and the first voltages; and
acquiring a second temperature, a second rate and a second voltage of a battery pack, and acquiring a second SOC of each second battery cell in the battery pack by the association table, where the battery pack includes multiple second battery cells.

In a possible implementation, acquiring the charging-discharging data of the first battery cell pack at different first temperatures and different first rates includes:
acquiring the different first temperatures according to a preset change parameter, and controlling a measuring space to reach the first temperatures, where the measuring space is used for placing the first battery cell pack;
if each first battery cell pack includes only one first battery cell, at each same first temperature, acquiring charging-discharging data of each first battery cell pack at the different first rates;
if each first battery cell pack includes at least one first battery cell, at each same first temperature, acquiring charging-discharging data of each first battery cell pack at the different first rates.

In a possible implementation, if each first battery cell pack includes only one first battery cell, the method further includes:
at each same first temperature, acquiring a first charging-discharging parameter of each first battery cell at a same first rate;
acquiring the charging-discharging data of the first battery cell pack according to a first average value of the first charging-discharging parameter of at least one first battery cell at the same first rate and the first charging-discharging parameter;
if each first battery cell pack includes at least one first battery cell, the method further includes:
at each same first temperature, acquiring a second charging-discharging parameter of each first battery cell pack at the same first rate;
acquiring the charging-discharging data of the first battery cell pack according to a second average value of the second charging-discharging parameter of at least one first battery cell pack at the same first rate and the second charging-discharging parameter.

In a possible implementation, establishing the association table of the first SOCs with the first temperatures, the first rates and the first voltages includes:
for each first battery cell pack, associating the first temperatures and the first rates for acquiring the charging-discharging data with the first voltages in the charging- discharging data to obtain a first association set;
associating the first voltages in the charging-discharging data for acquiring the first SOCs with the first SOCs to obtain a second association set;
acquiring the association table according to the first association set and the second association set, where a model of the first battery cell is consistent with a model of the second battery cell.

In a possible implementation, acquiring the second temperature, the second rate and the second voltage of the battery pack includes:
acquiring a historical current and a historical temperature of the battery pack in a preset historical time period, and acquiring the second voltage and the second rate according to the historical current;
acquiring the second temperature of the battery pack according to the historical temperature.

In a possible implementation, acquiring the second voltage according to the historical current includes:
acquiring a current variation according to the preset historical time period and the historical current;
acquiring a first coefficient according to the current variation and a first characteristic parameter of the battery pack;
acquiring a second coefficient according to the preset historical time period, the first characteristic parameter and a second characteristic parameter of the battery pack;
acquiring the second voltage according to the first coefficient and the second coefficient.

In a possible implementation, before controlling the measuring space to reach the first temperatures, the method further includes:
acquiring a start time node where a humidity of the measuring space does not exceed a preset humidity;
acquiring a standing time length of the measuring space according to the start time node and a current time node, where the standing time length is a time length when the humidity of the measuring space does not exceed the preset humidity continuously;
if the standing time length exceeds a preset time length, confirming to place the first battery cell pack in the measuring space.

In a second aspect, the present application provides a battery SOC evaluation apparatus, including:
an acquiring module, configured to acquire charging-discharging data of a first battery cell pack at different first temperatures and different first rates, where the number of the first battery cell pack is at least one, and the first battery cell pack includes a first battery cell;
a processing module, configured to acquire first SOCs of the first battery cell pack according to the charging-discharging data, where the charging-discharging data includes first voltages of the first battery cell pack;
an associating module, configured to establish an association table of the first SOCs with the first temperatures, the first rates and the first voltages;
an evaluating module, configured to acquire a second temperature, a second rate and a second voltage of a battery pack, and acquire a second SOC of each second battery cell in the battery pack by the association table, where the battery pack includes multiple second battery cells.

In a third aspect, the present application provides a battery SOC evaluation device, including: at least one processor and a memory;
where the memory stores computer-executable instructions;
the at least one processor executes the computer-executable instructions stored in the memory, so that the at least one processor executes the battery SOC evaluation method as described above.

In a fourth aspect, the present application provides a computer-readable storage medium, having a computer program stored thereon, where steps of the battery SOC evaluation method as described above are implemented when the computer program is executed by a processor.

Using the battery SOC evaluation method, the apparatus, the device and the medium provided by the present application, the charging-discharging data of the first battery cell pack is acquired at different first temperatures and different first rates, where the number of the first battery cell pack is at least one, and the first battery cell pack includes the first battery cell; the first SOCs of the first battery cell pack are acquired according to the charging-discharging data, where the charging-discharging data includes the first voltages of the first battery cell pack; the association table of the first SOCs with the first temperatures, the first rates and the first voltages is established; the second temperature, the second rate and the second voltage of the battery pack are acquired, and the second SOC of each second battery cell in the battery pack is acquired by the association table, where the battery pack includes multiple second battery cells.

In the above method, the association table is constructed through the first battery cell pack, and the second SOC of each second battery cell in the battery pack is evaluated through measurable data of the battery pack in the association table, which ensures that the second SOC of the battery pack is estimated accurately. When establishing the association table, the first battery cell pack is taken as an experimental object. The charging-discharging data of the first battery cell pack is acquired at different first temperatures and different first rates; the first SOCs of the first battery cell pack are acquired according to the charging-discharging data; and the measurable data, such as the first temperatures, the first rates and the first voltages, is associated with the first SOCs to establish the association table. The second temperature, the second rate and the second voltage of the battery pack are acquired, and an association relationship is looked up in the association table, which can acquire the second SOC of each second battery cell in the battery pack accurately and conveniently.

### BRIEF DESCRIPTION OF DRAWINGS

In order to illustrate technical solutions in embodiments of the present application or in the related art more clearly, the drawings needed to be used in the description of embodiments or the prior art will be briefly introduced below. Obviously, the drawings in the following description are some embodiments of the present application, and other drawings can be obtained by those of ordinary skills in the art according to these drawings without paying creative effort.

FIG. 1 is a schematic diagram of a scenario of battery SOC evaluation provided by an embodiment of the present application.

FIG. 2 is schematic flowchart 1 of a battery SOC evaluation method provided by an embodiment of the present application.

FIG. 3 is schematic flowchart 2 of a battery SOC evaluation method provided by an embodiment of the present application.

FIG. 4 is schematic flowchart 3 of a battery SOC evaluation method provided by an embodiment of the present application.

FIG. 5 is schematic flowchart 4 of a battery SOC evaluation method provided by an embodiment of the present application.

FIG. 6 is a diagram of a battery SOC evaluation apparatus provided by an embodiment of the present application.

FIG. 7 is a schematic diagram of hardware of a battery SOC evaluation device provided by an embodiment of the present application.

### DESCRIPTION OF EMBODIMENTS

In order to make purposes, technical solutions and advantages of embodiments of the present application clearer, the solutions of the embodiments of the present application will be described clearly and completely in connection with the drawings in the embodiments of the present application in the following. Obviously, the described embodiments are some embodiments of the present application, but not all embodiments. Based on the embodiments of the present application, all other embodiments obtained by those of ordinary skills in the art without paying creative effort belong to the protection scope of the present application.

Driven by the goal of “double carbon”, energy storage industry, as a supporting industry and a key promoter of energy structure adjustment, has wide application prospects in many fields such as traditional power generation, power transmission and distribution, power demand side, auxiliary services and new energy, etc. As a kind of electrochemical energy storage device, lithium-ion batteries (lithium batteries for short) are widely used in electrochemical energy storage and other fields. A electrochemical energy storage power station is mainly formed by a lithium battery pack, an energy storage converter (Power Conversion System, PCS), an isolation transformer, a battery management system, an energy management system and so on, to realize overall charging-discharging control of the system. Among them, a core of the electrochemical energy storage power station is the battery, and the safety of the battery directly affects the safety of the energy storage system.

Battery state of charge (SOC), as a quantitative evaluation of a state of charge stored in a battery, is used to characterize the ability of an energy storage system to store/release remaining power, and to prevent over-charge and over-discharge of the battery and ensure the safety of the energy storage system. However, a battery management system (BMS) cannot obtain the SOC by direct measurement, but can only perform comprehensive analysis and estimation on battery external characteristic parameters, such as a battery terminal voltage, etc. The accurate SOC evaluation ability can not only improve the safety of a battery pack, but also improve the overall performance and service life of the battery pack.

However, currently, methods for battery SOC estimation used in the BMS not only have low accuracy and are too complicated, but also mostly evaluate an overall SOC of the system, without accurately evaluating an SOC of each cell (battery cell), which will greatly reduce the scope and accuracy of the evaluation.

Therefore, the present application proposes an evaluation method based on the measurement on a battery cell, which can improve the accuracy of SOC evaluation.

Next, an implementation process of a battery SOC evaluation method proposed by the present application is explained in combination with the drawings and specific embodiments.

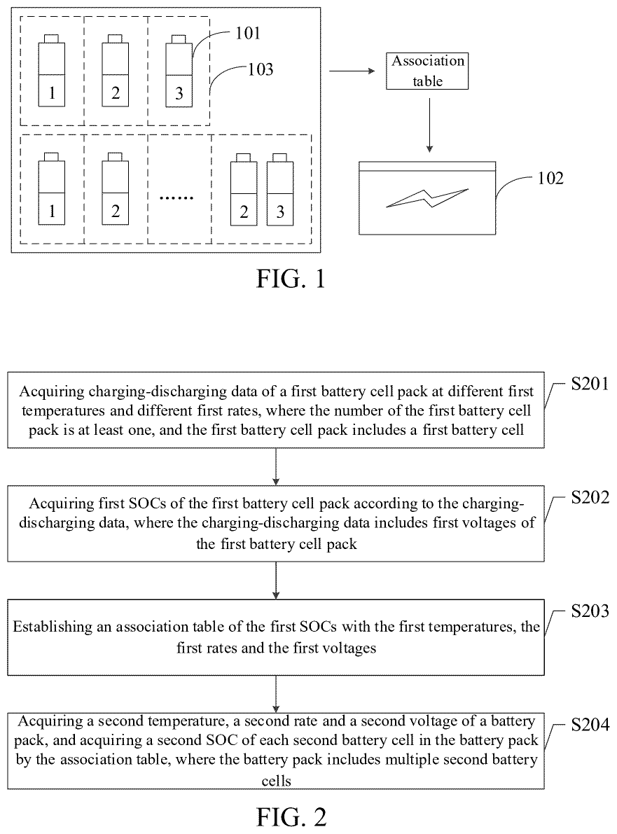

FIG. 1 is a schematic diagram of a scenario of battery SOC evaluation provided by an embodiment of the present application. As shown in FIG. 1, the system includes: first battery cells 101 and a battery pack 102. The battery pack 102 includes multiple second battery cells, and each of the first battery cells 101 and the second battery cells is a battery cell.

The battery pack 102 is formed by multiple second battery cells, and battery cells in the battery pack 102 may be connected in series. The first battery cells 101 may be sampling batteries, and data related thereto is used to establish an association table. The association table is used to express a relationship between battery external characteristic parameters and battery SOCs. The association table can be used to estimate an SOC of each second battery cell in the actual battery pack 102, which can identify the SOC of each battery cell of the battery pack simply and accurately.

Acquisition of external characteristic parameters of the first battery cells 101 includes acquiring charging-discharging data of a first battery cell pack 103 at different first temperatures and different first rates. The first battery cell pack is in units of first battery cells, and the first battery cells may be measured separately and may also be measured in combination. For example, when measuring three battery cells to establish the association table, battery cell a, battery cell b and battery cell c in the first battery cells 101 are measured separately. Or, battery cell d, battery cell e and battery cell f in the first battery cells 101 can be measured separately, and some battery cells can be selected and combined together for measurement, where battery e and battery f are selected and can be connected in series together for measurement.

First SOCs of the first battery cell pack 103 can be acquired according to the charging-discharging data of the first battery cell pack 103, and an association table of the first SOCs with the first temperatures, the first rates and the first voltages is established. The association table can be used for the battery pack 102. Measurement is performed on the battery pack 102 in real time to obtain a second temperature, a second rate and a second voltage of the battery pack 102, and by looking up the association table, a second SOC of each second battery cell in the battery pack 102 can be obtained by contrasting for the battery pack 102.

FIG. 2 is schematic flowchart 1 of a battery SOC evaluation method provided by an embodiment of the present application. As shown in FIG. 2, the method includes the following steps.

S201, acquiring charging-discharging data of a first battery cell pack at different first temperatures and different first rates, where the number of the first battery cell pack is at least one, and the first battery cell pack includes a first battery cell.

The first battery cell pack is placed in a certain measuring space. The measuring space is controlled to reach different first temperatures, and the measuring space is controlled to reach different first rates. The charging-discharging data of the first battery cell pack is acquired at different first temperatures and different first rates. The charging-discharging data is data related to battery charging and battery discharging, including a charging current, a discharging current, etc. There may be multiple first battery cell packs placed in the measuring space, and each first battery cell pack is formed by the first battery cell. Each first battery cell pack may have only one first battery cell and may also have one or more first battery cells. Specifically, a combination mode can be selected for each first battery cell pack according to actual requirements.

S202, acquiring first SOCs of the first battery cell pack according to the charging-discharging data, where the charging-discharging data includes first voltages of the first battery cell pack.

The charging-discharging data of the first battery cell pack includes first voltages and first currents of the first battery cell pack. The first voltages can be used as collectable corresponding data of the association table, and the first currents can be used to calculate the first SOCs of the first battery cell pack. Optionally, a way of calculating a first SOC is an ampere-hour integration method. A first current is a charging-discharging current of the first battery cell pack, and the first SOC of the first battery cell pack can be calculated by a formula of the ampere-hour integration method according to the first current and charging-discharging time of the first battery cell pack as well as the rated capacity of the first battery cell pack.

S203, establishing an association table of the first SOCs with the first temperatures, the first rates and the first voltages.

For each first battery cell pack, the charging-discharging data of the first battery cell pack at the same first temperature can be used to obtain one first SOC. The charging-discharging data includes the first voltage at the same first temperature, and the first rate is data obtained according to the first current and the rated capacity of the first battery cell pack. Then there is one first SOC, one first voltage and one first rate corresponding to the same one first temperature. The first SOC forms a correspondence with the first temperature, the first rate and the first voltage, and an association table can be established. Each first battery cell pack can correspond to one association table.

S204, acquiring a second temperature, a second rate and a second voltage of a battery pack, and acquiring a second SOC of each second battery cell in the battery pack by the association table, where the battery pack includes multiple second battery cells.

The association table includes a correspondence between the first SOCs and the first temperatures, the first rates and the first voltages, and each second battery cell of the battery pack is of the same type as the first battery cell pack, so the battery pack can use the association table. The temperature, the rate and the voltage are all measurable data, and the SOC is unmeasurable data. Temperature, rate and voltage measurement is performed on the battery pack to obtain the second temperature, the second rate and the second voltage. The second temperature, the second rate and the second voltage are mapped to the association table to find the corresponding SOC of the battery pack, and the second SOC of each second battery cell can be found.

In the embodiment of the present application, the association table is constructed through the first battery cell pack, and the second SOC of each second battery cell in the battery pack is evaluated through measurable data of the battery pack in the association table, which ensures that the second SOC of the battery pack is estimate accurately. When establishing the association table, the first battery cell pack is taken as an experimental object. The charging-discharging data of the first battery cell pack is acquired at different first temperatures and different first rates; the first SOCs of the first battery cell pack are acquired according to the charging-discharging data; and the measurable data, such as the first temperatures, the first rates and the first voltages, is associated with the first SOCs to establish the association table. The second temperature, the second rate and the second voltage of the battery pack are acquired, and an association relationship is looked up in the association table, which can acquire the second SOC of each second battery cell in the battery pack accurately and conveniently.

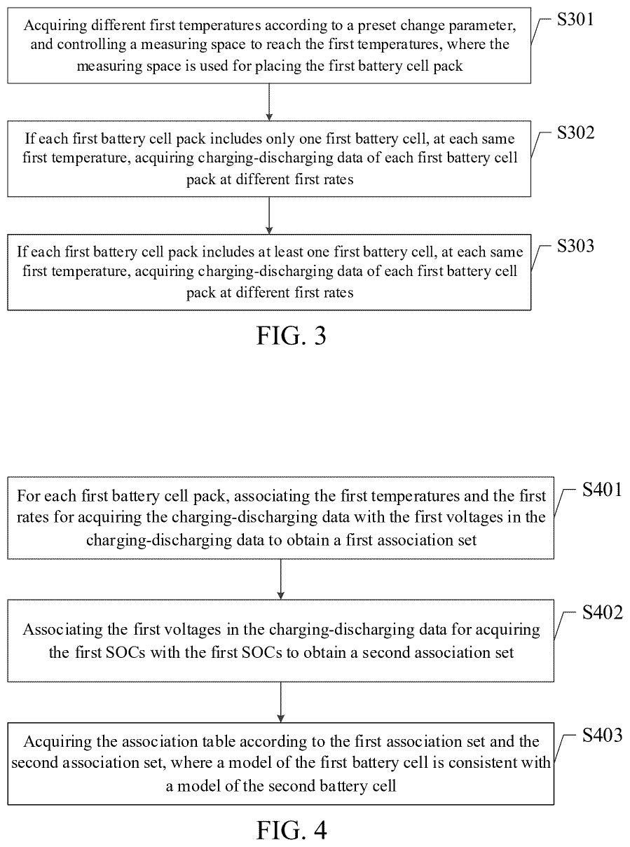

FIG. 3 is schematic flowchart 2 of a battery SOC evaluation method provided by an embodiment of the present application. As shown in FIG. 3, the method includes the following steps.

S301, acquiring different first temperatures according to a preset change parameter, and controlling a measuring space to reach the first temperatures, where the measuring space is used for placing the first battery cell.

The measuring space is used for placing the first battery cell pack. The charging-discharging data of the first battery cell pack need to be measured at different first temperatures, so the measuring space needs to be controlled according to a preset condition to complete temperature control. According to the preset change parameter, the measuring space can be controlled to reach different first temperatures. The change of the first temperatures may be a change in a certain gradient.

The preset change parameter is set as a certain gradient value, and according to the gradient value, the first temperature of the measuring space is adjusted on the basis of an appropriate temperature. For example, 25 degrees Celsius is an appropriate temperature, and a gradient value of the first temperature is set as 10 degrees Celsius, so the temperature setting of the first temperature may be 15 degrees Celsius, 25 degrees Celsius, 35 degrees Celsius, 45 degrees Celsius.

In order to ensure the environment for measuring the measuring space of the first battery cell pack meets the standard, the measuring space can be pre-processed.

Exemplary, before controlling the measuring space to reach the first temperatures, the method further includes:
acquiring a start time node where a humidity of the measuring space does not exceed a preset humidity;
acquiring a standing time length of the measuring space according to the start time node and a current time node, where the standing time length is a time length when the humidity of the measuring space does not exceed the preset humidity continuously;
if the standing time length exceeds a preset time length, confirming to place the first battery cell pack in the measuring space.

The humidity of the measuring space will affect the measurement of the first battery cell pack, so the measuring space should be standing in a stable and dry environment for a period of time. When the humidity of the measuring space does not exceed the preset humidity, then it is considered as being dry. The preset humidity may be set to 60% RH. When the humidity of the measuring space does not exceed 60% RH, then the environment of the measuring space is considered as being dry. The standing time length of the measuring space in the dry environment should exceed the preset time length, and if yes, it is confirmed to place the first battery cell pack in the measuring space. The standing time length may be set to 24 hours or longer time.

The measuring space has a corresponding start time node of reaching dryness and a current time node of keeping dry. The standing time length of the measuring space can be confirmed according to the start time node of being dry and the current time node of keeping dry for the measuring space.

S302, if each first battery cell pack includes only one first battery cell, at each same first temperature, acquiring charging-discharging data of each first battery cell pack at different first rates.

There may be multiple first battery cell packs, and each first battery cell pack may have one first battery cell. That is, only charging-discharging data of the battery cell is collected to establish an association table. Accordingly, at the same first temperature, the charging-discharging data of the first battery cell pack at different first rates is acquired, that is, at the same first temperature, charging-discharging data of each individual first battery cell at different first rates is acquired.

S303, if each first battery cell pack includes at least one first battery cell, at each same first temperature, acquiring charging-discharging data of each first battery cell pack at different first rates.

Each first battery cell pack may also have multiple first battery cells. Multiple first battery cells are selected according to requirements, and the first battery cells are combined. The first battery cell pack obtained after the combination may include one first battery cell and may also include multiple first battery cells. That is, charging-discharging data of the battery cell and charging-discharging data of some combined batteries can be collected to establish an association table. Accordingly, at the same first temperature, charging-discharging data of the first battery cell pack at different first rates is acquired, that is, at the same first temperature, charging-discharging data of the individual first battery cells and the combined first battery cells at different first rates are acquired.

The charging-discharging data of the first battery cell pack is acquired.

Exemplary, if each first battery cell pack includes only one first battery cell, the method further includes:
at each same first temperature, acquiring a first charging-discharging parameter of each first battery cell at the same first rate;
acquiring the charging-discharging data of the first battery cell pack according to a first average value of the first charging-discharging parameter of at least one first battery cell at the same first rate and the first charging-discharging parameter;
if each first battery cell pack includes at least one first battery cell, the method further includes:
at each same first temperature, acquiring a second charging-discharging parameter of each first battery cell pack at the same first rate;
acquiring the charging-discharging data of the first battery cell pack according to a second average value of the second charging-discharging parameter of at least one first battery cell pack at the same first rate and the second charging-discharging parameter.

No matter whether each first battery cell pack includes only one first battery cell or each first battery cell pack includes at least one first battery cell, the charging-discharging parameter of each corresponding first battery cell pack can be collected, and the charging-discharging parameter is the measured charging-discharging current and/or other data. If each first battery cell pack includes only one first battery cell, the first charging-discharging parameter is obtained; if each first battery cell pack includes at least one first battery cell, the second charging-discharging parameter is obtained. The first charging-discharging parameter and the second charging-discharging parameter may be directly selected as the charging-discharging data of the first battery cell pack, and may also be selected as the charging-discharging data of the first battery cell pack after taking an average value thereof.

In the embodiment of the present application, the charging-discharging data is measured for the battery cell, so as to facilitate the establishment of the association table that is related to the battery cell and used for SOC estimation and to facilitate the SOC evaluation of the battery pack.

FIG. 4 is schematic flowchart 3 of a battery SOC evaluation method provided by an embodiment of the present application. As shown in FIG. 4, the method includes the following steps.

S401, for each first battery cell pack, associating the first temperatures and the first rates for acquiring the charging-discharging data with the first voltages in the charging-discharging data to obtain a first association set.

The association table of the first SOCs with the first temperatures, the first rates and the first voltages may be not a function expression. The association table may be only used to associate corresponding input values and output values, where the input values include a temperature, a rate and a voltage, and the output value includes an SOC. When the input values are obtained by measurement, the corresponding output value can be obtained by looking up the association table, that is, the SOC of the battery is evaluated. For each first battery cell pack, there is an association between a certain first temperature, a certain first rate and a first voltage in the charging-discharging data obtained by measurement at the certain first temperature and the certain first rate, which is the first association set.

S402, associating the first voltages in the charging-discharging data for acquiring the first SOCs with the first SOCs to obtain a second association set.

For each first battery cell pack, its charging-discharging data measured at a certain first temperature and a certain first rate further includes a first current. The first current can be used to calculate a first SOC, and the calculated first SOC is associated with a first voltage in the charging-discharging data measured at the certain first temperature and the certain first rate as the second association set.

S403, acquiring the association table according to the first association set and the second association set, where a model of the first battery cell is consistent with a model of the second battery cell.

For each first battery cell pack, the first voltage in the charging-discharging data at the same first temperature and the same first rate are associated with the first SOC to obtain the association table.

The first association set and the second association set are combined to obtain the association table of the first SOCs with the first temperatures, the first rates and the first voltages, that is, to obtain an association table of temperatures, rates and voltages and SOCs. When the model of the first battery cell is consistent with the model of the second battery cell, the association table can be used for the battery pack measurement corresponding to the second battery cells.

The battery pack may be in a form of series connection or parallel connection. In order to evaluate the second SOC of the second battery cell therein, the same one negative electrode can be set for each second battery cell, and the second temperature, the second rate and the second voltage of each second battery cell can be obtained based on charging-discharging data of this negative electrode and a positive electrode of each second battery cell, so as to obtain the SOC of each second battery cell with reference to the association table.

In the embodiment of the present application, the SOC of each second battery cell in a charging and discharging process can be accurately evaluated, and SOC differences between different second battery cells within the battery pack can be identified, results of which can be applied to a strategy of recharging and balancing of abnormal batteries, improving the system consistency.

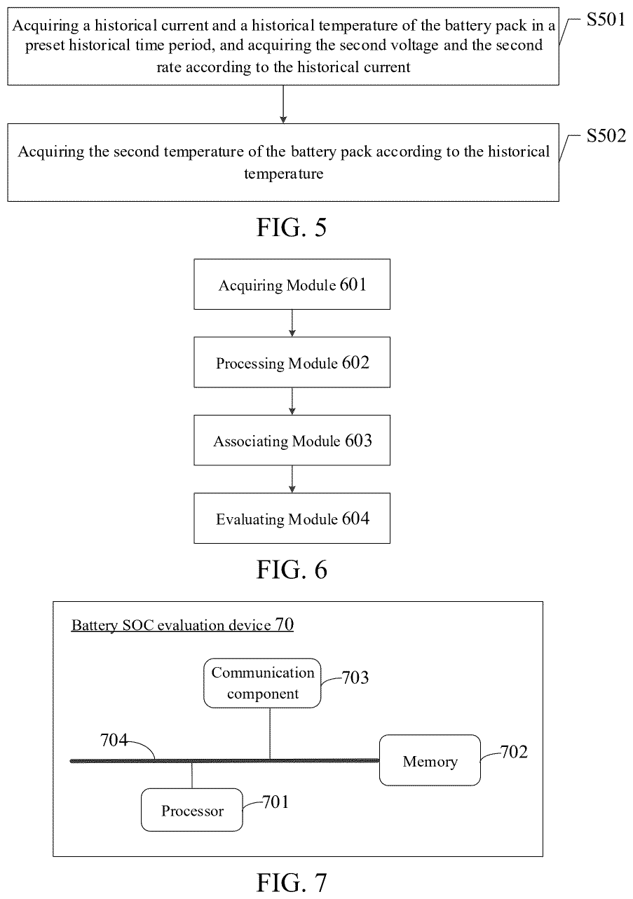

FIG. 5 is schematic flowchart 4 of a battery SOC evaluation method provided by an embodiment of the present application. As shown in FIG. 5, the method includes the following steps.

S501, acquiring a historical current and a historical temperature of the battery pack in a preset historical time period, and acquiring the second voltage and the second rate according to the historical current.

The battery pack has a corresponding temperature value in an actual use environment. The historical temperature can be collected in the preset historical time period, and the historical temperature can be obtained by performing collection once within the preset historical time period or by performing collection more than once to take an average value. The historical current of the battery pack also needs to be acquired in the preset historical time period, and the historical current may be continuously acquired. The second voltage and the second rate can be calculated according to the historical current, the historical temperature and a corresponding formula, and the second rate can be obtained according to a second current and the rated capacity of the second battery cell.

The second voltage can be calculated as follows, exemplarily:
acquiring a current variation according to the preset historical time period and the historical current;
acquiring a first coefficient according to the current variation and a first characteristic parameter of the battery pack;
acquiring a second coefficient according to the preset historical time period, the first characteristic parameter and a second characteristic parameter of the battery pack;
acquiring the second voltage according to the first coefficient and the second coefficient.

A first value of the first coefficient is acquired according to the current variation and a first parameter of the first characteristic parameter of the battery pack; a second value of the first coefficient is acquired according to the current variation and a second parameter of the first characteristic parameter of the battery pack.

A third value of the second coefficient is acquired according to the preset historical time period, the first parameter of the first characteristic parameter and a third parameter of the second characteristic parameter; a fourth value of the second coefficient is acquired according to the preset historical time period, the second parameter of the first characteristic parameter and a fourth parameter of the second characteristic parameter.

The second voltage is acquired according to the first value and the second value of the first coefficient as well as the third value and the fourth value of the second coefficient:

$$V = - dI * Rd * exp ( \frac{- dt}{Rd * Cd} ) - dI * Rd 2 * exp ( \frac{- dt}{Rd 2 * Cd 2} )$$

where V is a voltage compensation value, and the second voltage can be obtained by the voltage compensation value plus a voltage value in a current state; dI is the current variation, dt is the preset historical time period; exp(·) is a function with natural numbers as base numbers; Rd, Cd, Rd2 and Cd2 are different battery cell characteristic parameters respectively, namely, the first parameter of the first characteristic parameter, the third parameter of the second characteristic parameter, the second parameter of the first characteristic parameter and the fourth parameter of the second characteristic parameter; and * is a multiplication sign.

S502, acquiring the second temperature of the battery pack according to the historical temperature.

The historical temperature may be obtained by performing collection once within the preset historical time period or by performing collection more than once to take an average value, and can be directly used as the second temperature.

In the present application, battery cell impedance characteristics can also be taken into account, and then evaluation results can more accurately reflect an actual available power of the battery pack. At the same time, based on the evaluated SOC results and combining related control strategies, the safety performance and the service life of the lithium battery can be further improved.

FIG. 6 is a diagram of a battery SOC evaluation apparatus provided by an embodiment of the present application. As shown in FIG. 6, the apparatus includes: an acquiring module 601, a processing module 602, an associating module 603 and an evaluating module 604.

The acquiring module 601 is configured to acquire charging-discharging data of a first battery cell pack at different first temperatures and different first rates, where the number of the first battery cell pack is at least one, and the first battery cell pack includes a first battery cell.

The acquiring module 601 is further configured to: acquire the different first temperatures according to a preset change parameter, and control a measuring space to reach the first temperatures, where the measuring space is used for placing the first battery cell pack;
if each first battery cell pack includes only one first battery cell, at each same first temperature, acquire charging-discharging data of each first battery cell pack at the different first rates;
if each first battery cell pack includes at least one first battery cell, at each same first temperature, acquire charging-discharging data of each first battery cell pack at the different first rates.

The processing module 602 is configured to acquire first SOCs of the first battery cell pack according to the charging-discharging data, where the charging-discharging data includes first voltages of the first battery cell pack.

The associating module 603 is configured to establish an association table of the first SOCs with the first temperatures, the first rates and the first voltages.

The associating module 603 is further configured to: for each first battery cell pack, associate the first temperatures and the first rates for acquiring the charging-discharging data with the first voltages in the charging-discharging data to obtain a first association set;
associate the first voltages in the charging-discharging data for acquiring the first SOCs with the first SOCs to obtain a second association set;
acquire the association table according to the first association set and the second association set, where a model of the first battery cell is consistent with a model of the second battery cell.

The evaluating module 604 is configured to acquire a second temperature, a second rate and a second voltage of a battery pack, and acquire a second SOC of each second battery cell in the battery pack by the association table, where the battery pack includes multiple second battery cells.

The evaluating module 604 is further configured to: acquire a historical current and a historical temperature of the battery pack in a preset historical time period, and acquire the second voltage and the second rate according to the historical current;
acquire the second temperature of the battery pack according to the historical temperature.

The present application further provides a battery SOC evaluation device, including: at least one processor and a memory;
where the memory stores computer-executable instructions;
the at least one processor executes the computer-executable instructions stored in the memory, so that the at least one processor executes the battery SOC evaluation method as described above.

FIG. 7 is a schematic diagram of hardware of a battery SOC evaluation device provided by an embodiment of the present application. As shown in FIG. 7, the battery SOC evaluation device 70 provided by this embodiment includes: at least one processor 701 and a memory 702. The device 70 further includes a communication component 703. The processor 701, the memory 702 and the communication component 703 are connected via a bus 704.

In a specific implementation process, the at least one processor 701 executes computer-executable instructions stored in the memory 702, so that the at least one processor executes the battery SOC evaluation method as described above.

The specific implementation process of the processor 701 can be found in the above method embodiments. Implementation principles and technical effects thereof are similar, and will not be repeated here in this embodiment.

In the above embodiment shown in FIG. 7, it should be understood that the processor may be a central processing unit (CPU), and may also be other general-purpose processors, digital signal processors (DSPs), application specific integrated circuits (ASICs), etc. A general-purpose processor may be a microprocessor or the processor may be any conventional processor, etc. The method steps disclosed in combination with the present application can be directly embodied as being executed and completed by a hardware processor, or by a combination of hardware and software modules in the processor.

The memory may include a high-speed memory (RAM) and may also include a non-volatile memory (NVM), such as at least one disk memory.

The bus may be an industry standard architecture (ISA) bus, a peripheral component interconnect (PCI) bus or an extended industry standard architecture (EISA) bus, etc. The bus can be divided into an address bus, a data bus, a control bus, etc. For the convenience of representation, the bus in the drawings of the present application is not limited to only one bus or one type of bus.

The present application further provides a computer-readable storage medium. The computer-readable storage medium stores computer-executable instructions, and when a processor executes the computer-executable instructions, the battery SOC evaluation method as described above is implemented.

The above computer-readable storage medium can be realized by any type of volatile or nonvolatile storage devices or their combinations, such as a static random access memory (SRAM), an electrically erasable programmable read-only memory (EEPROM), an erasable programmable read-only memory (EPROM), a programmable read-only memory (PROM), a read-only memory (ROM), a magnetic memory, a flash memory, a magnetic disk or an optical disk. The readable storage medium may be any available medium that can be accessed by a general-purpose or special-purpose computer.

An exemplary readable storage medium is coupled to a processor so that the processor can read information from the readable storage medium and write information to the readable storage medium. Of course, the readable storage medium may also be a constituent part of the processor. The processor and the readable storage medium may be located in an application specific integrated circuit (ASIC). Of course, the processor and the readable storage medium may also exist as separate components in the device.

The division of the units is only a logical functional division, and there may be other division manners in actual implementation. For example, multiple units or components may be combined or integrated into another system, or some features may be ignored or not implemented. In addition, a mutual coupling or a direct coupling or communication connection shown or discussed may be an indirect coupling or communication connection through some interfaces, apparatuses or units, and may be electrical, mechanical or in other forms.

The units described as separate components may or may not be physically separated, and the components displayed as units may or may not be physical units, that is, they may be located in one place or distributed to multiple network units. Some or all of the units may be selected according to actual needs to achieve a purpose of the solution of the embodiment.

It can be understood by those skilled in the art that all or part of steps for implementing the above method embodiments can be completed by hardware related to program instructions. The foregoing program may be stored in a computer-readable storage medium. When the program is executed, the steps including the above method embodiments are executed. The foregoing storage medium includes a ROM, a RAM, a magnetic disk, an optical disk or other media that can store program codes.

Finally, it should be noted that those skilled in the art will easily think of other embodiments of the present application after considering the description and practicing the application disclosed herein. The present application is intended to cover any variations, uses or adaptations of the present application. These variations, uses or adaptations follow general principles of the present application and include common knowledge or conventional technical means in the art that the present application has not disclosed, and are not limited to the precise structures described above and shown in the drawings. Various modifications and changes can be made without departing from the scope thereof. The scope of the present application is limited only by the appended claims.

What is claimed is:

1. A battery state of charge (SOC) evaluation method, comprising:
acquiring charging-discharging data of a first battery cell pack at different first temperatures and different first rates, wherein the number of the first battery cell pack is at least one, and the first battery cell pack comprises a first battery cell;
acquiring first SOCs of the first battery cell pack according to the charging-discharging data, wherein the charging-discharging data comprises first voltages of the first battery cell pack;
establishing an association table of the first SOCs with the first temperatures, the first rates and the first voltages;
acquiring a second temperature, a second rate and a second voltage of a battery pack, and acquiring a second SOC of each second battery cell in the battery pack by the association table, wherein the battery pack comprises multiple second battery cells.

2. The method according to claim 1, wherein acquiring the charging-discharging data of the first battery cell pack at different first temperatures and different first rates comprises:
acquiring the different first temperatures according to a preset change parameter, and controlling a measuring space to reach the first temperatures, wherein the measuring space is used for placing the first battery cell pack;
if each first battery cell pack comprises only one first battery cell, at each same first temperature, acquiring charging-discharging data of each first battery cell pack at the different first rates;
if each first battery cell pack comprises at least one first battery cell, at each same first temperature, acquiring charging-discharging data of each first battery cell pack at the different first rates.

3. The method according to claim 2, wherein if each first battery cell pack comprises only one first battery cell, the method further comprises:
at each same first temperature, acquiring a first charging-discharging parameter of each first battery cell at a same first rate;
acquiring the charging-discharging data of the first battery cell pack according to a first average value of the first charging-discharging parameter of at least one first battery cell at the same first rate and the first charging-discharging parameter;
if each first battery cell pack comprises at least one first battery cell, the method further comprises:
at each same first temperature, acquiring a second charging-discharging parameter of each first battery cell pack at the same first rate;
acquiring the charging-discharging data of the first battery cell pack according to a second average value of the second charging-discharging parameter of at least one first battery cell pack at the same first rate and the second charging-discharging parameter.

4. The method according to claim 1, wherein establishing the association table of the first SOCs with the first temperatures, the first rates and the first voltages comprises:
for each first battery cell pack, associating the first temperatures and the first rates for acquiring the charging-discharging data with the first voltages in the charging-discharging data to obtain a first association set;
associating the first voltages in the charging-discharging data for acquiring the first SOCs with the first SOCs to obtain a second association set;
acquiring the association table according to the first association set and the second association set, wherein a model of the first battery cell is consistent with a model of the second battery cell.

5. The method according to claim 1, wherein acquiring the second temperature, the second rate and the second voltage of the battery pack comprises:
acquiring a historical current and a historical temperature of the battery pack in a preset historical time period, and acquiring the second voltage and the second rate according to the historical current;
acquiring the second temperature of the battery pack according to the historical temperature.

6. The method according to claim 5, wherein acquiring the second voltage according to the historical current comprises:
acquiring a current variation according to the preset historical time period and the historical current;
acquiring a first coefficient according to the current variation and a first characteristic parameter of the battery pack;
acquiring a second coefficient according to the preset historical time period, the first characteristic parameter and a second characteristic parameter of the battery pack;
acquiring the second voltage according to the first coefficient and the second coefficient.

7. The method according to claim 2, wherein before controlling the measuring space to reach the first temperatures, the method further comprises:
acquiring a start time node where a humidity of the measuring space does not exceed a preset humidity;
acquiring a standing time length of the measuring space according to the start time node and a current time node, wherein the standing time length is a time length when the humidity of the measuring space does not exceed the preset humidity continuously;
if the standing time length exceeds a preset time length, confirming to place the first battery cell pack in the measuring space.

8. A battery state of charge (SOC) evaluation device, comprising: at least one processor and a memory;
wherein the memory stores computer-executable instructions;
the at least one processor executes the computer-executable instructions stored in the memory, so that the at least one processor is configured to:
acquire charging-discharging data of a first battery cell pack at different first temperatures and different first rates, wherein the number of the first battery cell pack is at least one, and the first battery cell pack comprises a first battery cell;
acquire first SOCs of the first battery cell pack according to the charging-discharging data, wherein the charging-discharging data comprises first voltages of the first battery cell pack;
establish an association table of the first SOCs with the first temperatures, the first rates and the first voltages;
acquire a second temperature, a second rate and a second voltage of a battery pack, and acquire a second SOC of each second battery cell in the battery pack by the association table, wherein the battery pack comprises multiple second battery cells.

9. The device according to claim 8, wherein the at least one processor is specifically configured to:
acquire the different first temperatures according to a preset change parameter, and control a measuring space to reach the first temperatures, wherein the measuring space is used for placing the first battery cell pack;
if each first battery cell pack comprises only one first battery cell, at each same first temperature, acquire charging-discharging data of each first battery cell pack at the different first rates;
if each first battery cell pack comprises at least one first battery cell, at each same first temperature, acquire charging-discharging data of each first battery cell pack at the different first rates.

10. The device according to claim 9, wherein the at least one processor is specifically configured to:
if each first battery cell pack comprises only one first battery cell, at each same first temperature, acquire a first charging-discharging parameter of each first battery cell at a same first rate;
acquire the charging-discharging data of the first battery cell pack according to a first average value of the first charging-discharging parameter of at least one first battery cell at the same first rate and the first charging-discharging parameter;
if each first battery cell pack comprises at least one first battery cell,
at each same first temperature, acquire a second charging-discharging parameter of each first battery cell pack at the same first rate;
acquire the charging-discharging data of the first battery cell pack according to a second average value of the second charging-discharging parameter of at least one first battery cell pack at the same first rate and the second charging-discharging parameter.

11. The device according to claim 8, wherein the at least one processor is specifically configured to:
for each first battery cell pack, associate the first temperatures and the first rates for acquiring the charging-discharging data with the first voltages in the charging-discharging data to obtain a first association set;
associate the first voltages in the charging-discharging data for acquiring the first SOCs with the first SOCs to obtain a second association set;
acquire the association table according to the first association set and the second association set, wherein a model of the first battery cell is consistent with a model of the second battery cell.

12. The device according to claim 8, wherein the at least one processor is specifically configured to:
acquire a historical current and a historical temperature of the battery pack in a preset historical time period, and acquire the second voltage and the second rate according to the historical current;
acquire the second temperature of the battery pack according to the historical temperature.

13. The device according to claim 12, wherein the at least one processor is specifically configured to:
acquire a current variation according to the preset historical time period and the historical current;
acquire a first coefficient according to the current variation and a first characteristic parameter of the battery pack;
acquire a second coefficient according to the preset historical time period, the first characteristic parameter and a second characteristic parameter of the battery pack;
acquire the second voltage according to the first coefficient and the second coefficient.

14. The device according to claim 9, wherein the at least one processor is specifically configured to:
acquire a start time node where a humidity of the measuring space does not exceed a preset humidity;
acquire a standing time length of the measuring space according to the start time node and a current time node, wherein the standing time length is a time length when the humidity of the measuring space does not exceed the preset humidity continuously;
if the standing time length exceeds a preset time length, confirm to place the first battery cell pack in the measuring space.

15. A non-transitory computer-readable storage medium, having a computer program stored thereon, wherein the non-transitory computer-readable storage medium causes a processor to execute operations comprising:
acquiring charging-discharging data of a first battery cell pack at different first temperatures and different first rates, wherein the number of the first battery cell pack is at least one, and the first battery cell pack comprises a first battery cell;
acquiring first states of charge (SOCs) of the first battery cell pack according to the charging-discharging data, wherein the charging-discharging data comprises first voltages of the first battery cell pack;
establishing an association table of the first SOCs with the first temperatures, the first rates and the first voltages;
acquiring a second temperature, a second rate and a second voltage of a battery pack, and acquiring a second SOC of each second battery cell in the battery pack by the association table, wherein the battery pack comprises multiple second battery cells.

16. The non-transitory computer-readable storage medium according to claim 15, wherein acquiring the charging-discharging data of the first battery cell pack at different first temperatures and different first rates comprises:
acquiring the different first temperatures according to a preset change parameter, and controlling a measuring space to reach the first temperatures, wherein the measuring space is used for placing the first battery cell pack;
if each first battery cell pack comprises only one first battery cell, at each same first temperature, acquiring charging-discharging data of each first battery cell pack at the different first rates;
if each first battery cell pack comprises at least one first battery cell, at each same first temperature, acquiring charging-discharging data of each first battery cell pack at the different first rates.

17. The non-transitory computer-readable storage medium according to claim 16, wherein the non-transitory computer-readable storage medium causes the processor to execute operations further comprising:
if each first battery cell pack comprises only one first battery cell,
at each same first temperature, acquiring a first charging-discharging parameter of each first battery cell at a same first rate;
acquiring the charging-discharging data of the first battery cell pack according to a first average value of the first charging-discharging parameter of at least one first battery cell at the same first rate and the first charging-discharging parameter;
if each first battery cell pack comprises at least one first battery cell,
at each same first temperature, acquiring a second charging-discharging parameter of each first battery cell pack at the same first rate;
acquiring the charging-discharging data of the first battery cell pack according to a second average value of the second charging-discharging parameter of at least one first battery cell pack at the same first rate and the second charging-discharging parameter.

18. The non-transitory computer-readable storage medium according to claim 15, wherein establishing the association table of the first SOCs with the first temperatures comprises:
for each first battery cell pack, associating the first temperatures and the first rates for acquiring the charging-discharging data with the first voltages in the charging-discharging data to obtain a first association set;
associating the first voltages in the charging-discharging data for acquiring the first SOCs with the first SOCs to obtain a second association set;
acquiring the association table according to the first association set and the second association set, wherein a model of the first battery cell is consistent with a model of the second battery cell.

19. The non-transitory computer-readable storage medium according to claim 15, wherein acquiring the second temperature, the second rate and the second voltage of the battery pack comprises:
acquiring a historical current and a historical temperature of the battery pack in a preset historical time period, and acquiring the second voltage and the second rate according to the historical current;
acquiring the second temperature of the battery pack according to the historical temperature.

20. The non-transitory computer-readable storage medium according to claim 19, wherein acquiring the second voltage according to the historical current comprises:
acquiring a current variation according to the preset historical time period and the historical current;
acquiring a first coefficient according to the current variation and a first characteristic parameter of the battery pack;
acquiring a second coefficient according to the preset historical time period, the first characteristic parameter and a second characteristic parameter of the battery pack;
acquiring the second voltage according to the first coefficient and the second coefficient.
